(19) United States
(12) Patent Application Publication
(10) Pub. No.: US 2007/0197011 A1
(43) Pub. Date: Aug. 23, 2007

(54) Method for improving self-aligned silicide extendibility with spacer recess using a stand-alone recess etch integration

(75) Inventors: Anadi Srivastava, Austin, TX (US); Paul A. Grudowski, Austin, TX (US); Dharmesh Jawarani, Round Rock, TX (US); Rode R. Mora, Austin, TX (US)

Correspondence Address: FORTKORT & HOUSTON P.C., 9442 N. CAPITAL OF TEXAS HIGHWAY, ARBORETUM PLAZA ONE, SUITE 500, AUSTIN, TX, 78759, US

(73) Assignee: Freescale Semiconductor Inc.

(21) Appl. No.: 11/360,318

(22) Filed: Feb. 22, 2006

(51) Int. Cl. H01L 21/4763; H01L 21/3205

(52) U.S. Cl. 438/592

(57) ABSTRACT

A method is provided for making a silicided gate (209). In accordance with the method, a semiconductor substrate (202) is provided which has a gate (209) disposed thereon and which has a spacer (219) disposed adjacent to the gate. The spacer is subjected to a recess etch which exposes a lateral portion of the gate. An implant region (215) is then created adjacent to the spacer, and a layer of silicide (225) is formed which extends over the exposed lateral portion of the gate.

### FIELD OF THE DISCLOSURE

The present disclosure relates generally to semiconductor devices, and more particularly to methods for forming silicide layers in semiconductor devices.

### BACKGROUND OF THE DISCLOSURE

Various metal silicides, such as cobalt silicide, are used in the art as contact materials for forming contacts to silicon in CMOS devices. The use of metal silicides is desirable due to the low resistivity, high stability, and small lattice mismatch with silicon that is achievable with these materials. Moreover, as compared to many other contact materials, metal silicides can be readily patterned into relatively small dimensions.

Unfortunately, the ongoing trend toward smaller device sizes in semiconductor fabrication processes is currently testing the limitations of silicide technology. In particular, as polysilicon gate lengths decrease, it becomes increasingly challenging to form uniform layers of silicide on these gates. Indeed, at dimensions below about 50 nm, extensive voiding and silicide spiking can occur during silicide formation. Consequently, at these dimensions, uniform silicide films cannot be formed in a reproducible manner using current technologies.

Some attempts have been made in the art to overcome this problem. For example, in some applications, overetching of spacer structures has been employed to expose additional surface area on the gate. This technique permits the formation of more uniform silicide films on gate structures of smaller gate lengths, since it increases the total surface area available for the formation of the silicide film. However, the reductions in gate lengths achievable with this technique have been found to be incremental at best, since the electrical properties of the resulting structures are found to degrade rapidly as the extent of overetching increases. In particular, overetching is found to have a negative product yield impact outside of a narrow recess window, and that this recess window has been found to be inadequate for preserving the robustness of cobalt silicide and other suicides at gate lengths of less than 40 nm.

There is thus a need in the art for a method for forming silicided polysilicon gates in semiconductor devices which overcomes the aforementioned infirmity. In particular, there is a need in the art for a method for reproducibly forming silicided polysilicon gates in which the gates have reduced dimensions, without adversely affecting the electrical properties of the semiconductor device. There is further a need for such a method which is suitable for preserving the robustness of cobalt silicide and other silicides at gate lengths below 40 nm. These and other needs may be met by the devices and methodologies described herein.

### BRIEF DESCRIPTION OF THE DRAWINGS

FIG. 1 is an illustration of a semiconductor structure during a step of a prior art process;

FIG. 2 is an illustration of a semiconductor structure during a step of a prior art process;

FIG. 3 is an illustration of a semiconductor structure during a step of a prior art process;

FIG. 4 is an illustration of a semiconductor structure during a step of a prior art process;

FIG. 5 is an illustration of a semiconductor structure during a step of a prior art process;

FIG. 6 is an illustration of a semiconductor structure during a step of a process in accordance with the teachings herein;

FIG. 7 is an illustration of a semiconductor structure during a step of a process in accordance with the teachings herein;

FIG. 8 is an illustration of a semiconductor structure during a step of a process in accordance with the teachings herein;

FIG. 9 is an illustration of a semiconductor structure during a step of a process in accordance with the teachings herein;

FIG. 10 is an illustration of a semiconductor structure during a step of a process in accordance with the teachings herein;

FIG. 11 is an illustration of a semiconductor structure during a step of a process in accordance with the teachings herein; and

FIG. 12 is an illustration of a semiconductor structure during a step of a process in accordance with the teachings herein.

### DETAILED DESCRIPTION

In one aspect, a method for making a silicided gate structure is provided herein. In accordance with the method, a semiconductor substrate is provided having a gate electrode disposed thereon and having a spacer adjacent to the gate electrode. The structure is subjected to a recess etch which exposes a lateral portion of the gate. An implant region is created adjacent to the spacer, and a layer of silicide is formed over the lateral portion of the gate.

In another aspect, a method for making a silicided gate structure is provided. In accordance with the method, a semiconductor substrate is provided which has a gate disposed thereon. A conformal layer of spacer material is deposited over the gate, and the conformal layer is etched to define first and second spacer structures therein, wherein the first and second spacer structures are adjacent to the gate. The first spacer is subjected to a second etch which exposes a first lateral portion of the gate, after which first and second implant regions are created adjacent to the first and second spacers. A layer of silicide is then formed over the first lateral portion of the gate.

These and other aspects of the present disclosure are described in greater detail below.

It has now been found that the aforementioned needs in the art may be met by utilizing a stand-alone recess etch, after the main spacer etch is used to initially define the spacer structures, to expose additional lateral surface area of the gate for silicidation. The increase in gate surface area provided by this approach permits the reproducible formation of silicide film on gates of reduced lengths (e.g., less than 40 nm) without voiding. Moreover, the use of a separate recess etch, rather than a main spacer overetch, to define the final spacer dimensions and to expose lateral portions of the gate for silicidation, has a number of benefits. In particular, this approach creates greater process flexibility in that it permits independent optimization of spacer etch and recess etch conditions, and also provides greater integration flexibility with respect to positioning of the recess etch and pre- and post-etch treatments. Moreover, a standalone recess etch opens a wider process space than the integrated etch typical in the prior art, and facilitates further transistor structural optimization.

As an illustration of the greater process flexibility afforded by the methodologies described herein, it is to be noted that the constraints governing a main spacer etch (which may include a separate spacer overetch) and those governing a recess etch are frequently quite different. Thus, for example, across-wafer uniformity requirements for a recess etch are typically much less demanding than for the main spacer etch. In particular, in the main spacer etch, across-wafer uniformity should be as high as possible, since the source/drain implants in the device are self-aligned to the spacer edge, and since across-wafer variations in spacer base-width produce an undesirable increase in variation of across-wafer transistor performance. By contrast, since there are typically few, if any, implants performed subsequent to the recess etch which are of a type likely to affect transistor performance, across-wafer uniformity in the recess etch is typically less critical.

Similarly, while the main spacer etch must typically have a high etch rate to provide adequate manufacturing throughput, lower etch rates can be tolerated for the recess etch, since the amount of material to be removed in the recess etch is typically much less than in the main spacer etch. Also, while controllability requirements needed to achieve manufacturing run-to-run repeatability are typically quite stringent for the main spacer etch, they are less demanding for the recess etch, since the sensitivity of transistor responses to the recess etch can be reduced by appropriate positioning of this process within the integration.

On the other hand, selectivity to an etch termination layer such as oxide is far more critical in the recess etch than in the main spacer etch. This is due, in part, to the fact that the main spacer etch typically has a thicker layer of oxide to stop on than the recess etch.

In light of the above, it will be appreciated that, while the main spacer etch and the recess etch share some requirements, they differ in other requirements which can drive process optimization for the two etches in different directions. As a result, the optimal chemistries and process conditions for the two etches may be quite different. Thus, in one contemplated embodiment, the optimal chemistry for the main spacer etch is HBr/CF₄ and the optimal chemistry for the controlled overetch is HBr/Cl₂, while the optimal chemistry for the recess etch is CH₃F/O₂.

The methodologies described herein can be better understood in the context of the prior art process described in FIGS. 1-5. In the process depicted therein, a semiconductor device is formed on a silicon substrate 101. The device is isolated from other semiconductor devices formed on the substrate 101 by field oxide shallow trench isolation areas 103. A polysilicon gate 105 is formed on a gate oxide layer 107. A lightly doped drain implant (LDD) oxide 109 is disposed on the sidewalls of the gate 105. A pair of shallow implant regions 115 are then created in a portion of the substrate 101 adjacent to the LDD oxide layer 109 on each side of the gate 105.

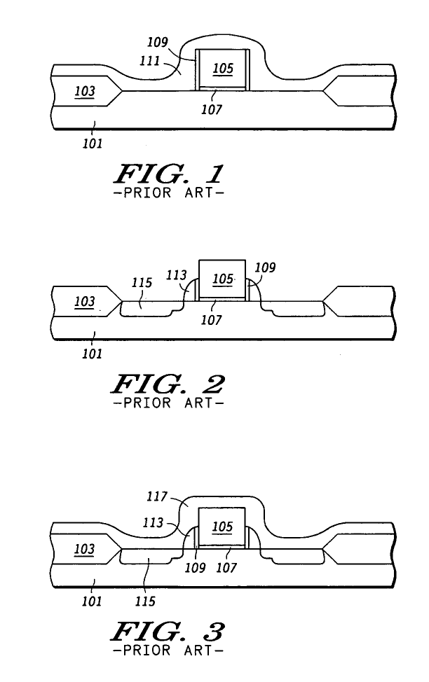

A layer of spacer material 111, such as silicon oxide or silicon nitride, is deposited conformally over the structure. The layer of spacer material 111 is then etched with a suitable etchant to define spacer structures 113 therein as shown in FIG. 2. However, in contrast to conventional etching techniques which are geared toward a structure in which the spacers 113 completely cover the gate sidewalls, the spacer material layer 111 is deliberately overetched to expose a portion of the sidewall of the gate 105. The overetch also removes any exposed portions of the LDD oxide 109. Once the spacers 113 are formed, deep implant regions 121 are created in the substrate by implantation. The structure may then be heated to activate the dopants in the deep implant regions 121.

As shown in FIG. 3, a refractory metal layer 117 is then conformally deposited over the semiconductor wafer. Due to the overetching performed in the previous step, the refractory metal layer 117 comes into contact with the exposed portion of the sidewalls of the gate 105. When the semiconductor wafer is subjected to one or more heating steps, as through a rapid thermal anneal (RTA) process, a low resistivity silicide is formed in those areas where the refractory metal layer 117 has come into contact with either the polysilicon of the gate 105 or the silicon of the deep implant regions 121.

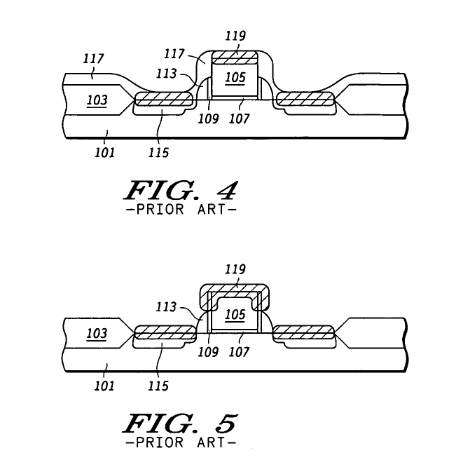

The resulting structure is depicted in FIG. 4 following the rapid thermal annealing steps utilized to form silicide regions 119 on the deep implant regions 121 and the gate 105. The silicide region 119 on the gate 105 extends to, and overhangs, the sidewalls of the gate 105. By contrast, silicide is not formed on the spacers 113 or the field oxide regions 103. Any unreacted metal is then removed by a suitable wet etch chemistry to achieve the structure depicted in FIG. 5. A second RTA may be performed to form the low resistivity silicide (which may be, for example, CoSi₂, TiSi₂, or NiSi).

As will be appreciated from FIG. 5, the process described in FIGS. 1-5 is advantageous in that the overetch procedure described therein results in an increased gate surface area over which silicide can be formed, without any increase in the gate length. However, this process is inherently limited by the fact that the overetch process also defines the location of the deep implant regions 121. Consequently, as the extent of the overetch increases, the width of the spacers 113 decreases, and the separation between the deep implant regions 121 and the gate 105 becomes smaller. Beyond a relatively minimal amount of overetching, this is found to result in current leakage and other problems that degrade the electrical performance of the device. On the other hand, if the extent of the overetch is limited to avoid this problem, the additional surface area of the gate that is available for silicidation is also limited, and hence the reduction in gate length achievable with the process is minimal.

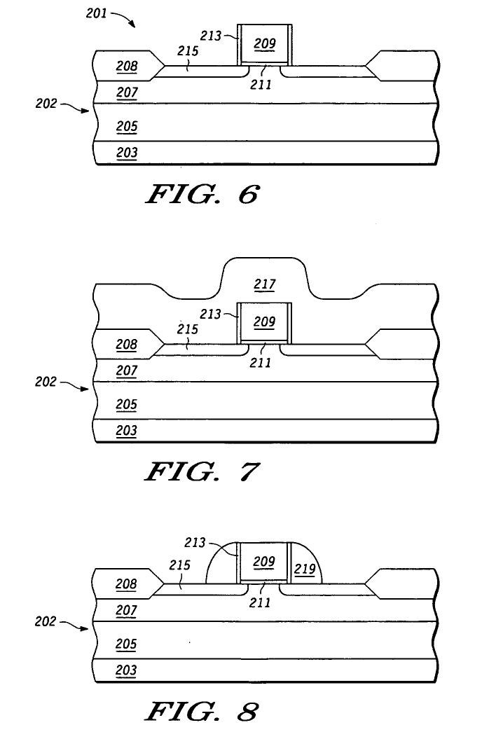

These shortcomings are addressed by the methodologies disclosed herein, which may be appreciated with respect to the first non-limiting embodiment disclosed in FIGS. 6-12. As shown in FIG. 6, a semiconductor structure 201 is provided which comprises a wafer 203, a buried oxide layer 205 and an active layer 207 (referred to collectively in this example as substrate 202). Hence, substrate 202 is a semiconductor-on-insulator (SOI) wafer. It will be appreciated, of course, that in possible variations of this embodiment, bulk wafers and other types of substrates could be used instead.

A series of field oxide regions 208 are provided to electronically isolate the individual devices that are created on the substrate 202. A gate 209 is disposed on the active layer 207 and is separated therefrom by a gate oxide layer 211. A second oxide layer 213, which may be, for example, a lightly doped drain implant (LDD) oxide, is disposed on the sides of the gate 209. A pair of shallow implant regions 215 are present in the active layer 207 on each side of the gate. Such implant regions may be created by a suitable ion implantation process or an appropriate sequence of ion implantation processes, followed by a thermal anneal to cause the diffusion of the implant regions 215. Since the diffusion is somewhat isotropic, this also has the effect of causing the implant regions 215 to extend slightly underneath the gate 209.

As shown in FIG. 7, a layer of a suitable spacer material 217 is disposed over the structure. The spacer material 217 is then anisotropically etched to produce a pair of spacer structures 219 adjacent to the gate 209 as shown in FIG. 8. Various spacer materials and etchants are known to the art, and the exact choice of spacer material and etchant (or etchants) will typically be dictated by the particular semiconductor device being formed, the intended use of the device, and the process parameters used to fabricate the device.

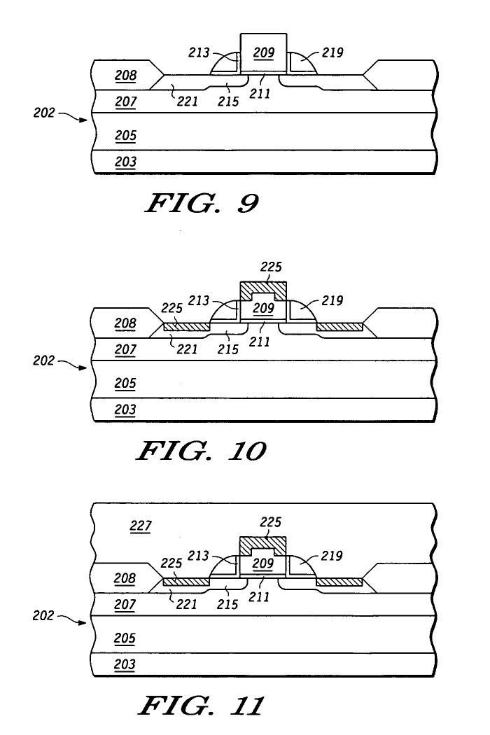

As depicted in FIG. 9, the spacer structures 219 are then subjected to a (preferably anisotropic) recess etch which reduces the height of the spacer structures 219 to below the height of the gate 209. The structure is then subjected to a second ion implantation step to create second (deep) implant regions 221 which are aligned to the edges of the spacer structures 219 as defined by the first recess etch. The second implant regions 221 are then subjected to a thermal anneal to cause them to diffuse deeper into the active layer 207. Again, the diffusion is somewhat isotropic, so this process has the effect of causing the second implant regions 221 to extend slightly underneath the spacer structures 219.

As shown in FIG. 10, a refractory metal layer 225, which may comprise metals such as Co, Ti, Ni, TiN, or various combinations or alloys of the foregoing, is then conformally deposited over the structure. Due to the recess etch of the previous step, the refractory metal layer 225 comes into contact with both the top and exposed side portions of the gate 209. When the structure is subjected to one or more heating steps, such as a rapid thermal anneal (RTA) process, a low resistivity silicide is formed in those areas where the refractory metal layer 225 is in contact with the material (preferably polysilicon) of the gate 209 or the material (preferably silicon) of the active layer 207. The rapid thermal annealing may be performed at conventional temperatures and processing conditions.

As can be appreciated from FIG. 10, the silicide region 225 on the gate 209 extends to, and overhangs, the sidewalls of the gate 209. Silicide is not formed on the spacers 219 or the field oxide regions 208. The unreacted metal is then removed by a suitable wet etch chemistry. In some embodiments, a second RTA may be performed to form the low resistivity silicide (which may be, for example, CoSi₂, TiSi₂, NiSi).

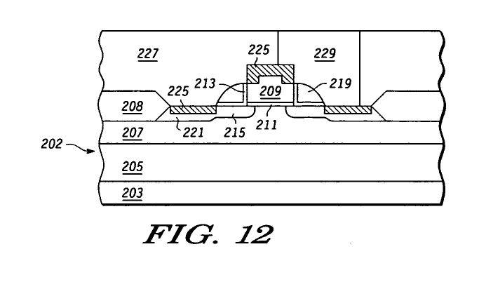

Once the silicide regions 225 are formed, the formation of the local interconnect or contact is then performed. This involves the deposition of an interlayer dielectric 227 as shown in FIG. 11. The interlayer dielectric 227 may be, for example, silicon dioxide derived from TEOS. Following the deposition of the dielectric layer, as shown in FIG. 12, an opening 229 is then formed in the interlayer dielectric 227 by an etch that is highly selective to the silicide 225 so that it does not etch through the silicide 225 into the device or the gate 209. The silicide region 225 which covers the gate sidewall exposed by the recess etching may, in some embodiments, help to prevent the preferential attacking of the spacers 219 and the LDD oxide 213. Hence, after the local interconnect etch or contact etch is performed, the profile of the spacers 219 remains intact.

The remaining processing steps used to complete the device are well known in the art. Typically, these steps involve the deposition of a conductive material within the opening 229 that has been etched in the preceding step. The conductive material may be, for example, tungsten or a suitable alloy such as TiW. The conductive material serves as a local interconnect and, in this particular example, contacts both the silicide region 225 of the gate 209 and the silicide region 225 which is in electrical contact with the active layer 207 (and the implant regions 221 defined therein, which serve as the source and drain regions of the transistor). Thus, the process results in a semiconductor structure that includes a gate 209 equipped with spacer structures 219 and silicide regions 225 that are present on the gate 209 and on the active layer 207. The portion of the silicide region 225 disposed on the gate 209 is in contact with both the top surface of the gate 209 and a portion of the sides of the gate 209.

One skilled in the art will appreciate that various other process steps may be added to the process described herein without departing from the present teachings. For example, the recess etch may include various pre-etch and post-etch cleaning steps, as well as post-etch metrology steps. Moreover, the recess etch may be employed at any desirable point in the process, though it will typically be performed sometime after the main spacer etch used to define the spacer structures, and prior to any silicide pre-clean steps.

The recess etch process described herein also affords a number of advantages beyond those discussed above. In particular, the partitioning of the spacer etching into a main spacer etch and a recess etch creates opportunities for process integration optimization in addition to the reductions in gate length and improved silicide layer stability that have been noted. Thus, for example, by inserting the recess etch into the process prior to the silicide pre-clean step, and by minimizing the duration of the (typically HF) pre-clean, a reduction in silicide stringer formation may be achieved.

Moreover, the recess etch described herein can be utilized to minimize the impact of uneven removal during spacer formation of spacer material along the (typically polysilicon) sidewall of the gate due to line edge roughness. In particular, if the same anisotropic etch used to define the spacer structures is also used to create the recess in the spacer structures, line edge roughness will contribute to uneven removal of the spacer material at the spacer structure/gate interface. By contrast, a combination of: (1) appropriate positioning of the recess etch within the process flow and (2) interposition of suitable isotropic wet or dry cleans between the main spacer etch and the recess etch in the process described herein can be used to compensate for this problem, thus reducing or eliminating the uneven removal of this material.

As another advantage, the use of a recess etch in addition to the main spacer etch offers greater process and process integration flexibility than the type of spacer overetch process described in FIGS. 1-5. Thus, for example, this approach allows for the selective creation of different recesses and different spacer widths for different device classes. It also offers the ability to minimize liner oxide loss through the optimization of recess etch selectivity, and the integration of additional etch chemistries into the process which, while ideal for use as a recess etch, might not be optimal for initial spacer formation.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

What is claimed is:

1. A method for making a silicided gate structure, comprising:
providing a semiconductor substrate having a gate disposed thereon and having a spacer disposed adjacent to the gate;
subjecting the spacer to a recess etch which exposes a lateral portion of the gate;
creating an implant region adjacent to the spacer; and
forming a layer of silicide over the exposed lateral portion of the gate.

2. The method of claim 1, wherein the layer of silicide also extends over a portion of the substrate adjacent to the spacer structure.

3. The method of claim 1, wherein the layer of silicide is formed by depositing a conformal layer of a refractory metal such that the conformal layer is in contact with the first and second lateral portions of the gate.

4. The method of claim 3, wherein the refractory metal is selected from the group consisting of Co, Ti, Ni, and NiSi.

5. The method of claim 1, wherein the layer of silicide comprises cobalt silicide.

6. The method of claim 1, wherein the gate has a dielectric layer disposed thereon which separates the spacer from the gate, and wherein the recess etch removes any exposed portion of the dielectric layer.

7. The method of claim 6, wherein the step of creating an implant region adjacent to the spacer involves implanting a dopant into a substrate adjacent to the spacer, and wherein the implantation is aligned with the spacer.

8. The method of claim 7, wherein the device has first and second implant regions in the substrate, wherein the second implant region is formed by an implantation that occurs after the recess etch and that is aligned with the spacer, and wherein the first implant region is formed by an implantation that is aligned with the gate.

9. The method of claim 8, wherein the recess etch reduces the width of the spacer.

10. The method of claim 8, wherein said first and second implant regions form the source and drain regions of a transistor.

11. The method of claim 8, wherein the first and second implant regions are each formed by implantation of a dopant followed by diffusion.

12. The method of claim 1, wherein the recess etch is selective to the material of the gate.

13. The method of claim 12, wherein a dielectric layer is disposed between the spacer and the gate, and wherein the recess etch also etches the dielectric layer.

14. The method of claim 1 wherein, prior to the recess etch, the spacer covers the entire side of the electrode.

15. A method for making a silicided gate structure, comprising:
providing a semiconductor substrate having a gate disposed thereon;
depositing a conformal layer of spacer material over the gate;
subjecting the conformal layer to a first etch so as to define first and second spacer structures therein, wherein the first and second spacer structures are adjacent to the gate;
subjecting the first spacer to a second etch which exposes a first lateral portion of the gate;
creating first and second implant regions adjacent to the first and second spacers; and
forming a layer of silicide over the first lateral portion of the gate.

16. The method of claim 15, wherein the second spacer is subjected to the second etch so as to expose a second lateral portion of the gate, and wherein the step of forming a layer of silicide over the first lateral portion of the gate further involves forming the layer of silicide over the second lateral portion of the gate.

17. The method of claim 15, wherein the layer of silicide also extends over a portion of the substrate adjacent to the first and second spacer structures.

18. The method of claim 15, wherein the layer of silicide is formed by depositing a conformal layer of a refractory metal such that the conformal layer is in contact with the first and second lateral portions of the gate.

19. The method of claim 18, wherein the refractory metal is selected from the group consisting of Co, Ti, Ni, and NiSi.

20. The method of claim 15, wherein the layer of silicide comprises cobalt silicide.
